(19) United States
(12) Patent Application Publication
(10) Pub. No.: US 2017/0207209 A1
(43) Pub. Date: Jul. 20, 2017

(54) INTEGRATED CIRCUITS WITH HIGH VOLTAGE AND HIGH DENSITY CAPACITORS AND METHODS OF PRODUCING THE SAME

(71) Applicant: Globalfoundries Singapore Pte. Ltd., Singapore (SG)

(72) Inventors: Bo Yu, Singapore (SG); Boon Guan Oon, Singapore (SG); Shaoqiang Zhang, Singapore (SG); Purakh Raj Verma, Singapore (SG); Guan Huei See, Singapore (SG); Yuzhan Wang, Singapore (SG)

(21) Appl. No.: 14/995,949

(22) Filed: Jan. 14, 2016

(51) Int. Cl. H01L 27/01; H01L 49/02

(52) U.S. Cl. CPC H01L 27/013; H01L 28/40

(57) ABSTRACT

Integrated circuits and methods of producing the same are provided. In an exemplary embodiment, an integrated circuit includes a high voltage capacitor having a first high voltage plate, a second high voltage plate directly overlying the first high voltage plate, and a high voltage dielectric film between the first and second high voltage plates. The integrated circuit also includes a high density capacitor with a first high density plate that is about co-planar with the second high voltage plate, a second high density plate directly overlying the first high density plate, and a thin high density dielectric film positioned between the first and second high density plates.

### TECHNICAL FIELD

The technical field generally relates to integrated circuits with high voltage and high density capacitors and methods of producing the same, and more particularly relates to integrated circuits with high voltage and high density capacitors as well as precision metal resistors and methods of producing the same.

### BACKGROUND

Capacitors are one type of electronic component used in many integrated circuits. Capacitors include two conductive plates separated by a dielectric layer. A charge can be temporarily stored on one of the conductive plates, and that charge can then be used for a wide variety of purposes. The dielectric layer can be polarized to store energy, so the dielectric layer increases the capacitor's charge capacity. When storing energy, there is an electric field across the dielectric layer, a positive charge on one of the conductive plates, and a negative charge on the other conductive plate.

Different capacitor designs have different properties, such as the amount of charge stored and the potential difference between the conductive plates. The capacitance of a capacitor is the ratio of the amount of electric charge (denoted by the symbol Q) on the conductive plates to the potential difference (measured in volts) between the conductive plates. Sometimes it is desirable for a capacitor to be capable of maintaining a large potential difference between the conductive plates (e.g., for a high voltage capacitor), and in other circumstances it is desirable for a capacitor to store a large amount of electric charge (e.g., for a high density capacitor). A thicker dielectric layer tends to have a smaller permittivity, and smaller permittivities are more conducive to high voltage capacitors than to high density capacitors. Therefore, the manufacturing steps are somewhat different for producing a high voltage capacitor and a high density capacitor, and the incorporation of different manufacturing steps tends to drive up the cost of production. As such, integrated circuits generally include either high voltage or high density capacitors, but not both.

Accordingly, it is desirable to provide integrated circuits that include both high voltage and high density capacitors, and methods for producing the same. In addition, it is desirable to provide integrated circuits that with additional electronic components formed with the capacitors, which tends to reduce the cost of such integrated circuits, and methods of producing the same. Furthermore, other desirable features and characteristics of the present embodiment will become apparent from the subsequent detailed description and the appended claims, taken in conjunction with the accompanying drawings and this background of the invention.

### BRIEF SUMMARY

Integrated circuits and methods of producing the same are provided. In an exemplary embodiment, an integrated circuit includes a high voltage capacitor having a first high voltage plate, a second high voltage plate directly overlying the first high voltage plate, and a high voltage dielectric film between the first and second high voltage plates. The integrated circuit also includes a high density capacitor with a first high density plate that is about co-planar with the second high voltage plate, a second high density plate directly overlying the first high density plate, and a thin high density dielectric film positioned between the first and second high density plates.

An integrated circuit is provided in another embodiment. The integrated circuit includes a high voltage capacitor overlying a substrate, where the high voltage capacitor includes a first high voltage plate and a second high voltage plate directly overlying the first high voltage plate. A high voltage dielectric film is positioned between the first and second high voltage plates, where the high voltage dielectric film has a high voltage dielectric film thickness. A high density capacitor also overlies the substrate. The high density capacitor includes a first high density plate, a second high density plate directly overlying the first high density plate, and a thin high density dielectric film between the first and second high density plates. The thin high density dielectric film has a thin high density dielectric film thickness that is less than the high voltage dielectric film thickness.

A method of producing an integrated circuit is provided in yet another embodiment. The method includes forming a first high voltage plate in a first interlayer dielectric, and forming a thick dielectric layer overlying the first high voltage plate and the first interlayer dielectric. A first electrode layer is formed overlying the thick dielectric layer, and a thin dielectric layer is formed overlying the first electrode layer. The thin dielectric layer has a thickness that is less than a thickness of the thick dielectric layer. A second electrode layer is formed overlying the thin dielectric layer. A high density capacitor is formed, where the high density capacitor includes a portion of the first electrode layer, a portion of the second electrode layer, and a portion of the thin dielectric layer. A high voltage capacitor is also formed, where the high voltage capacitor includes the first high voltage plate, a portion of the thick dielectric layer, and a portion of the first electrode layer.

### BRIEF DESCRIPTION OF THE DRAWINGS

The present embodiments will hereinafter be described in conjunction with the following drawing figures, wherein like numerals denote like elements, and wherein:

FIGS. 1-7 are cross-sectional views illustrating portions of an integrated circuit and methods for its fabrication in accordance with exemplary embodiments.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description. Embodiments of the present disclosure are generally directed to integrated circuits and methods for fabricating the same. The various tasks and process steps described herein may be incorporated into a more comprehensive procedure or process having additional steps or functionality not described in detail herein. In particular, various steps in the manufacture of integrated circuits are well-known and so, in the interest of brevity, many conventional steps will only be mentioned briefly herein or will be omitted entirely without providing the well-known process details.

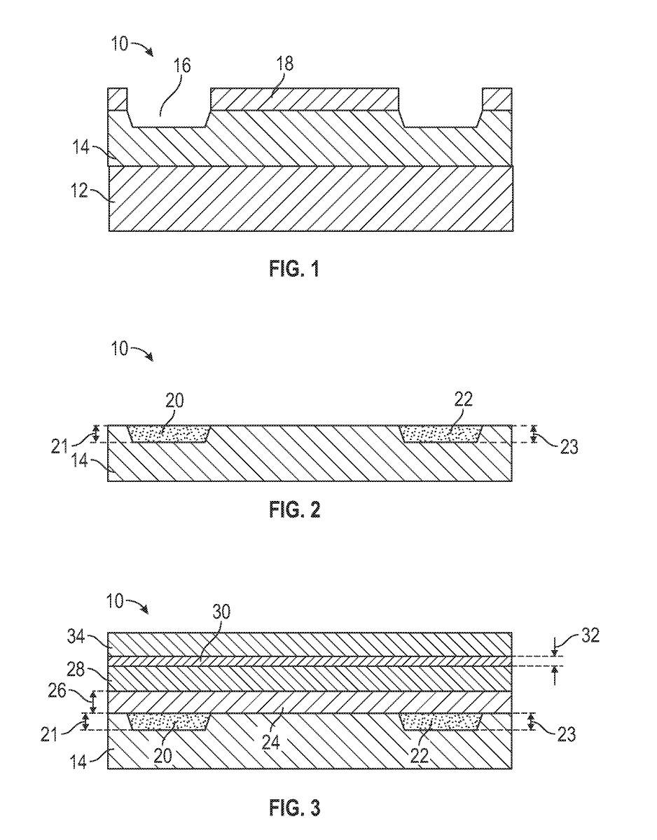

Reference is made to an exemplary embodiment illustrated in FIG. 1. An integrated circuit 10 includes a substrate 12 comprising semiconductor material. As used herein, the term “semiconductor material” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. In many embodiments, the substrate 12 primarily includes a monocrystalline silicon semiconductor material. The substrate 12 may be a bulk silicon wafer (as illustrated) or may be a thin layer of silicon on an insulating layer (commonly known as silicon-on-insulator or SOI, not illustrated) that, in turn, is supported by a carrier wafer. One or more electronic components (not illustrated) may be formed in or on the substrate 12 as is typical for many integrated circuits 10.

A first interlayer dielectric 14 overlies the substrate 12, where the first interlayer dielectric is an electrically insulating material. As used herein, an “electrically insulating material” is a material with a resistivity of about 1×10⁴ ohm meters or more, and an “electrically conductive material” is a material with a resistivity of about 1×10⁴ ohm meters or less. As used herein, the term “overlying” means “over” such that an intervening layer may lie between the first interlayer dielectric 14 and the substrate 12, and “on” such that the first interlayer dielectric 14 physically contacts the substrate 12. Moreover, the term “directly overlying” means a vertical line passing through the upper component also passes through the lower component, such that at least a portion of the upper component is directly over at least a portion of the lower component. It is understood that the integrated circuit 10 may be moved such that the relative “up” and “down” positions change, so reference to a “vertical” line means a line that is about perpendicular to the surface of the substrate 12. In an exemplary embodiment, the first interlayer dielectric 14 includes silicon dioxide, which may be formed by chemical vapor deposition using silane and oxygen, but many other electrically insulating materials or methods of formation may be used in alternate embodiments.

A first ILD gap 16 may be formed in an upper surface of the first interlayer dielectric 14, where the first ILD gap 16 extends into the first interlayer dielectric 14 for some distance but does not penetrate or pass completely through the first interlayer dielectric 14. In one exemplary embodiment, a first ILD hard mask 18 is formed overlying the first interlayer dielectric 14, such as by reacting ammonia and dichlorosilane in a low pressure chemical vapor deposition furnace to form silicon nitride for the first ILD hard mask 18. A layer of photoresist (not shown) is used for patterning the first ILD hard mask 18 to form the first ILD gap 16. The photoresist may be deposited by spin coating and patterned by exposure to light or other electromagnetic radiation through a mask with transparent sections and opaque sections. The light causes a chemical change in the photoresist such that either the exposed portions or the non-exposed portions can be selectively removed. The desired locations may be removed with an organic solvent, and the photoresist remains overlying the other areas of the first ILD hard mask 18. Exposed portions of the first ILD hard mask 18 can then be selectively removed, such as with a hot phosphoric acid etch, while the first ILD hard mask 18 underlying the remaining photoresist remains in place. The patterned first ILD hard mask 18 exposes the portions of the first interlayer dielectric 14 where the first ILD gap 16 will be formed while protecting other areas of the first interlayer dielectric 14. Photoresist may be selectively removed with an oxygen containing plasma after the first ILD hard mask 18 is patterned.

The exposed areas of the first interlayer dielectric 14 are etched with an etchant that is selective to the material of the first interlayer dielectric 14 over the material of the first ILD hard mask 18. For example, a wet etch with dilute hydrofluoric acid is selective to silicon dioxide (which may be in the first interlayer dielectric 14) over silicon nitride (which may be in the first ILD hard mask 18). In an exemplary embodiment, the depth of the first ILD gap 16 is determined by the time the etch is allowed to proceed, but in alternate embodiments an etch stop layer (not illustrated) may be formed within the first interlayer dielectric 14 to better control the depth of the first ILD gap 16, and a dry etch technique such as a reactive ion etch may be used. Many other etchants or etching techniques may be used in alternate embodiments, as understood by those skilled in the art, so the example described herein is merely exemplary and is not intended to limit the means of formation. Photoresists and hard masks may be used for patterning and forming many components of the integrated circuit 10, and repetitive discussions of this process are generally omitted to simplify and clarify this description.

Referring to FIG. 2 with continuing reference to FIG. 1, the first ILD hard mask 18 is removed, such as with a wet etch using hot phosphoric acid. The first ILD gaps 16 may be filled with an electrically conductive material to form a first high voltage plate 20 and an optional third high density plate 22. The electrically conductive material formed in the first ILD gap 16 is metallic in some embodiments, and may include about 80 mass percent copper or more in some embodiments. However, other electrically conductive materials and/or other metals may be used in alternate embodiments. In an exemplary embodiment, the first high voltage plate 20 and optional third high density plate 22 may be formed by depositing copper by electroless or electrolytic plating from a solution such as a sulfuric acid copper bath, and subsequent chemical mechanical planarization to remove the copper overburden. A copper seed layer (not illustrated) may be formed to improve adhesion between the first interlayer dielectric 14 and the first high voltage plate 20 and/or the third high density plate 22.

In some embodiments, the first high voltage plate 20 and the third high density plate 22 are formed at the same time using the same process techniques. As such, the properties of the first high voltage plate 20 and the third high density plate 22 may be substantially the same. As used herein, the term “substantially the same” means about the same, where the subject matter is intended to be the same but may vary slightly due to process variability or process errors. For example, the first high voltage plate 20 and the third high density plate 22 may be substantially co-planar, meaning a distance between bottom surfaces of (1) the first high voltage plate 20 and (2) the third high density plate 22 and a top surface of the substrate 12 (illustrated in FIG. 1) are within about 10 percent or each other, or within about 5 percent of each other, or within about 1 percent of each other in various embodiments. As used herein, the term “co-planar” refers to the components being substantially co-planar on a plane that is substantially parallel to the top surface of the substrate 12. In a similar manner, a composition of the first high voltage plate 20 is substantially the same as a composition of the third high density plate 22. For example, the mass percent of each element in the first high voltage plate 20 is within about 10 percent, or about 5 percent, or about 1 percent of the mass percent of that element in the third high density plate 22 in various embodiments. Also, a thickness 21 of the first high voltage plate 20 and a thickness 23 of the third high density plate 22 may be substantially the same, such as within about 10 percent, or 5 percent, or 1 percent of each other in various embodiments.

Reference is now made to an exemplary embodiment illustrated in FIG. 3. A thick dielectric layer 24 is formed overlying the first interlayer dielectric 14, the first high voltage plate 20, and the optional third high density plate 22. The thick dielectric layer 24 includes an electrically insulating material, and may include silicon nitride in some embodiments. Silicon nitride can be formed by low pressure chemical vapor deposition using ammonia and polydimethyl silane. The thick dielectric layer 24 may have a thickness (indicated by reference number 26) of from about 500 angstroms to about 2,000 angstroms, or from about 500 angstroms to about 3,000 angstroms, or from about 500 angstroms to about 5,000 angstroms in various embodiments. The thickness 26 of the thick dielectric layer 24 may be set such that the thick dielectric layer 24 has a pre-determined permittivity, so the thickness 26 of the thick dielectric layer 24 may vary somewhat based on the material composition of the thick dielectric layer 24. The thick dielectric layer 24 may serve as cap layer for the first interlayer dielectric 14 and any components formed therein in some embodiments, where a cap layer can limit atomic migration during subsequent annealing steps.

In an exemplary embodiment, a first electrode layer 28 is formed overlying the thick dielectric layer 24, where the first electrode layer 28 is formed of an electrically conductive material. In some embodiments, the first electrode layer 28 includes metals, such as titanium nitride, tantalum nitride, tantalum, or others. In some embodiments, the first electrode layer 28 includes about 50 mass percent or more of titanium, tantalum, or a combination thereof. A thin dielectric layer 30 is formed overlying the first electrode layer 28, where the thin dielectric layer 30 is formed of an electrically insulating material. The thin dielectric layer 30 may include silicon nitride, which can be formed as described above, but the thin dielectric layer 30 may include several other materials in alternate embodiments. For example, the thin dielectric layer 30 may include silicon dioxide, silicon-carbon-nitrogen-hydrogen compounds known by the name NBLoK, high K dielectric materials such as hafnium oxide, aluminum hafnium oxide, aluminum oxide, or other materials. The thin dielectric layer 30 has a thickness indicated by the reference number 32 that is thinner than the thickness 26 of the thick dielectric layer 24. For example, the thickness 32 of the thin dielectric layer 30 may be from about 50 angstroms to about 500 angstroms, or from about 100 angstroms to about 500 angstroms, or from about 50 to about 400 angstroms in various embodiments. As with the thick dielectric layer 24 described above, the thickness 32 of the thin dielectric layer 30 may be set to produce a certain permittivity, so the thickness 32 may vary depending on the material of the thin dielectric layer 30. In general, the permittivity of the thick dielectric layer 24 is less than the permittivity of the thin dielectric layer 30. A second electrode layer 34 is formed overlying the thin dielectric layer 30, where the second electrode layer 34 includes an electrically conductive material. As with the first electrode layer 28 described above, the second electrode layer 34 may include a metal, and may include about 50 mass percent or more of titanium, tantalum, or a combination thereof. An electrode layer hard mask and photoresist (not illustrated) are formed and patterned overlying the second electrode layer 34, in the same manner as described above.

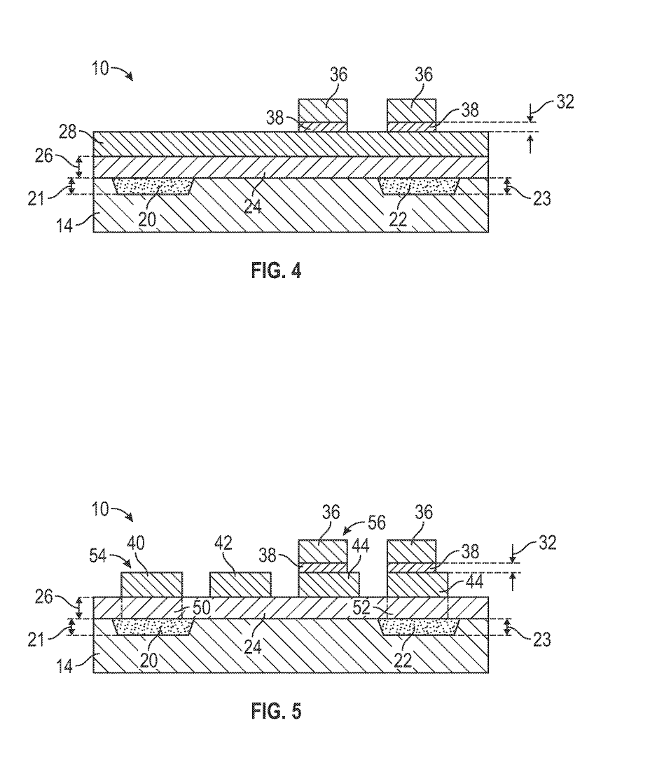

Referring to the exemplary embodiment illustrated in FIG. 4, with continuing reference to FIG. 3, the second electrode layer 34 and the thin dielectric layer 30 are removed except for at selected locations to form one or more second high density plates 36 and one or more thin high density dielectric films 38. The second high density plate 36 directly overlies and, in some embodiments, is disposed directly upon the thin high density dielectric film 38. In an embodiment with the second electrode layer 34 including titanium nitride, the second electrode layer 34 may be removed in areas not covered by the electrode layer hard mask (not illustrated) with a reactive ion etch using chlorine and argon. In embodiments with the thin dielectric layer 30 including silicon nitride, the thin dielectric layer 30 may be removed where not covered by the electrode layer hard mask (not illustrated) with a reactive ion etch. In one optional embodiment, the second high density plate 36 may directly overlie the third high density plate 22, but in other embodiments the second high density plate 36 directly overlies the first interlayer dielectric 14 and the substrate 12 (illustrated in FIG. 1), but does not directly overlie a third high density plate 22. In some embodiments, there may be more than one second high density plate 36, and some of the second high density plates 36 may directly overlie respective third high density plates 22 and some of the second high density plates 36 may be positioned in areas that do not directly overlie a third high density plate 22.

Portions of the first electrode layer 28 are then selectively removed to form a second high voltage plate 40, a resistor plate 42, and a first high density plate 44, as illustrated in FIG. 5 with continuing reference to FIG. 4. The portions of the first electrode layer 28 may be selectively removed using lithography and an optional hard mask (not illustrated), in the same manner as described above. In some embodiments, the second high voltage plate 40 directly overlies the first high voltage plate 20, and the portion of the thick dielectric layer 24 that is positioned between the first and second high voltage plates 20, 40 serves as a high voltage dielectric film 50. The first high voltage plate 20 may extend beyond the area covered by the second high voltage plate 40 to facilitate an electrical connection to the first high voltage plate 20. The resistor plate 42 overlies the thick dielectric layer 24, and the first high density plate 44 directly underlies the second high density plate 36 and the thin high density dielectric film 38. The first high density plate 44 may extend beyond the area covered by the second high density plate 36 to facilitate separate electrical connections, as mentioned above for the first and second high voltage plates 20, 40. In embodiments where the second high density plate 36 directly overlies the third high density plate 22, the first high density plate 44 also directly overlies the third high density plate 22. In such embodiments, the portion of the thick dielectric layer 24 positioned between the first and third high density plates 44, 22 serves as a thick high density dielectric film 52. The thick high density dielectric film 52 and the high voltage dielectric film 50 are formed from the thick dielectric layer 24 in some embodiments, so all three components have substantially the same thickness and composition, as described above for the first high voltage plate 20 and the third high density plate 22.

The second high voltage plate 40, the resistor plate 42, and the first high density plate 44 are formed from the first electrode layer 28, so the second high voltage plate 40, the resistor plate 42, and the first high density plate 44 are all about co-planar and all have about the same composition. For example, the composition of any element in one of the second high voltage plate 40, the resistor plate 42, or the first high density plate 44 may be within about 10 mass percent, or within about 5 mass percent, or within about 1 mass percent of the composition of that element in any other of the second high voltage plate 40, the resistor plate 42, and the first high density plate 44, in various embodiments. The second high voltage plate 40, the resistor plate 42, and the first high density plate 44 are all about co-planar, so a distance between a top surface of the substrate 12 (illustrated in FIG. 1) and a bottom surface of the second high voltage plate 40, the resistor plate 42, or the first high density plate 44 is within about 10 percent, or about 5 percent, or about 1 percent of the distance between the top surface of the substrate 12 (illustrated in FIG. 1) and a bottom surface of any other of the second high voltage plate 40, the resistor plate 42, and the first high density plate 44, in various embodiments.

The first and second high voltage plates 20, 40 are separated by the high voltage dielectric film 50, and this forms a high voltage capacitor 54. The first and second high density plates 44, 36 are separated by the thin high density dielectric film 38, and this forms a high density capacitor 56. The permittivity of the thin high density dielectric film 38 is greater than that of the high voltage dielectric film 50 in some embodiments, at least in part because the thin high density dielectric film 38 is thinner than the high voltage dielectric film 50, so the high voltage capacitor 54 is capable of maintaining a larger potential difference (voltage) between the capacitor plates than the high density capacitor 56. Because of the difference in permittivity, the high density capacitor 56 is capable of storing a larger amount of charge than the high voltage capacitor 54 for equivalent areas of the respective capacitor plates. The method of producing the high voltage and high density capacitors 54, 56 within the same integrated circuit 10, as described herein, allows for greater circuit design flexibility compared to an integrated circuit with only one of the high voltage or high density capacitors 54, 56. Additionally, the use of one layer to produce plates for two different types of capacitors may also reduce manufacturing costs compared to separate plate production for each type of capacitor. The high density capacitor 56 that includes a third high density plate 22 further increases the circuit design flexibility, because such a high density capacitor 56 can store a larger amount of charge for a given area than a high density capacitor 56 without a third high density plate 22.

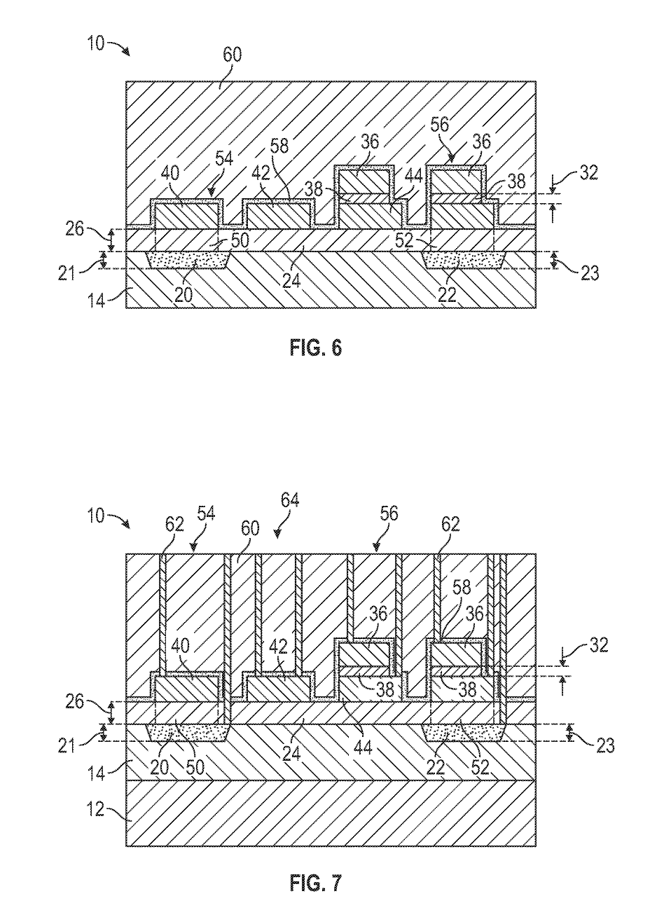

Referring to FIG. 6, an etch stop layer 58 may be formed overlying the second high voltage plate 40, the resistor plate 42, the second high density plate 36, the thick dielectric layer 24, and any other components that are exposed. In an exemplary embodiment, the etch stop layer 58 includes silicon nitride, NBLoK, silicon carbon nitride, or other electrically insulating materials. Silicon nitride may be deposited by chemical vapor deposition using ammonia and dichlorosilane, for example, but other material may also be used in the etch stop layer 58 in various embodiments. A second interlayer dielectric 60 that includes, for example, silicon dioxide may be formed overlying the etch stop layer 58 and the components underlying the etch stop layer 58. An upper surface of the second interlayer dielectric 60 may be planarized, such as with chemical mechanical planarization, in some embodiments.

Contacts 62 may be formed through the second interlayer dielectric 60 to form an electrical connection with each of the capacitor plates (20, 22, 36, 40, and 44), and with the resistor plate 42, as illustrated in FIG. 7. Vias (not illustrated) may be formed through the second interlayer dielectric 60 using lithography and a reactive ion etch selective to the material of the second interlayer dielectric 60 over the material of the etch stop layer 58, followed by a selective removal of the etch stop layer 58 in the vias (not illustrated.) In an example where the second interlayer dielectric 60 includes silicon dioxide and the etch stop layer 58 includes silicon nitride, the second interlayer dielectric 60 may be selectively removed with a reactive ion etch using hydrogen bromide and silicon tetrafluoride with oxygen, and the etch stop layer 58 can be selectively removed with a hot phosphoric acid wet etch. The contacts 62 may then be formed within the vias (not illustrated). In an exemplary embodiment, the contacts 62 include an adhesion layer, a barrier layer, and a plug (not individually illustrated), which are sequentially deposited. For example, an adhesion layer of titanium may be formed by low pressure chemical vapor deposition using titanium pentachloride, a barrier layer of titanium nitride may be formed by chemical vapor deposition using titanium tetrabromide and ammonia, and a plug of tungsten may be formed by chemical vapor deposition using tungsten hexafluoride and hydrogen. Other types of contacts are also possible, such as copper or other conductive materials.

At least two contacts 62 are in electrical communication with the resistor plate 42, where the two contacts 62 are a set distance apart along the resistor plate 42, thus forming a resistor 64. The resistor plate 42 has a cross sectional area between the two contacts 62. All materials have some resistance to the flow of electricity, and that resistance is related to the cross sectional area perpendicular to the flow of electricity and the distance the electricity flows through the material. Therefore, the resistance of the resistor 64 can be controlled by establishing or selecting the material of the resistor plate 42, the cross-sectional area of the resistor plate 42 between the two contacts 62, and the distance between the two contacts 62 through the resistor plate 42. Other factors may also influence the resistance of the resistor 64, such as the shape of the resistor plate 42, the amount or type of silicide formed at the contact point between the resistor plate 42 and the contacts 62, and other factors. The resistor plate 42 may be metallic, so the resistance and temperature coefficient of resistance of the resistor plate 42 may be less than that of a resistor that has a polysilicon resistor plate. The term “metallic,” as used herein, means a material that includes at least about 50 mass percent of a metal or more. As such, the resistor 64 may be a precision metal resistor 64 as compared to a resistor formed with a polysilicon resistor plate. As used herein, a “precision resistor” is a resistor primarily formed of a material with a lower resistance and temperature coefficient of resistance than that of polysilicon. The economical process described above can be used to form (1) the resistor 64, (2) the high voltage capacitor 54, and (3) the high density capacitor 56 that all overlie the substrate 12. A circuit designer has increased design flexibility for an integrated circuit 10 when the two different types of capacitors are included in a single integrated circuit 10, and the addition of the resistor 64 further improves design flexibility.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

1. An integrated circuit comprising:
a high voltage capacitor comprising a first high voltage plate, a second high voltage plate directly overlying the first high voltage plate, and a high voltage dielectric film positioned between the first high voltage plate and the second high voltage plate;
a high density capacitor comprising a first high density plate that is about co-planar with the second high voltage plate, a second high density plate directly overlying the first high density plate; and a thin high density dielectric film positioned between the first high density plate and the second high density plate;
an etch stop layer overlying the high voltage capacitor and the high density capacitor, wherein the etch stop layer comprises an electrically insulating material; and
a second interlayer dielectric overlying the etch stop layer.

2. The integrated circuit of claim 1 further comprising:
a resistor comprising a resistor plate, wherein the resistor plate is about co-planar with the second high voltage plate and the first high density plate, wherein the etch stop layer overlies the resistor.

3. The integrated circuit of claim 2 further comprising:
a thick dielectric layer underlying the resistor plate; and
a first interlayer dielectric underlying the thick dielectric layer.

4. The integrated circuit of claim 2 wherein:
the resistor plate, the second high voltage plate, and the first high density plate have about the same composition.

5. The integrated circuit of claim 1 wherein a thickness of the high voltage dielectric film is greater than a thickness of the thin high density dielectric film.

6. The integrated circuit of claim 1 wherein the high density capacitor further comprises a third high density plate underlying the first high density plate.

7. The integrated circuit of claim 6 further comprising:
a thick high density dielectric film positioned directly between the first high density plate and the third high density plate, wherein a composition of the thick high density dielectric film is about the same as a composition of the high voltage dielectric film.

8. The integrated circuit of claim 7 wherein a thickness of the thick high density dielectric film is about the same as a thickness of the high voltage dielectric film.

9. The integrated circuit of claim 6 wherein the first high voltage plate and the third high density plate have about the same composition.

10. The integrated circuit of claim 6 wherein the first high voltage plate and the third high density plate are about co-planar.

11. The integrated circuit of claim 1 wherein:
the second high voltage plate and the first high density plate have about the same composition.

12. The integrated circuit of claim 1 wherein the first high voltage plate comprises about 80 mass percent copper or more, and the second high voltage plate comprises about 50 mass percent of a metal selected from the group consisting of titanium, tantalum, and a combination thereof.

13. The integrated circuit of claim 1 wherein a permittivity of the high density dielectric film is greater than a permittivity of the high voltage dielectric film.

14. An integrated circuit comprising:
a high voltage capacitor overlying a substrate, wherein the high voltage capacitor comprises a first high voltage plate, a second high voltage plate directly overlying the first high voltage plate, and a high voltage dielectric film positioned between the first high voltage plate and the second high voltage plate, wherein the high voltage dielectric film has a high voltage dielectric film thickness;
a high density capacitor overlying the substrate, wherein the high density capacitor comprises a first high density plate, a second high density plate directly overlying the first high density plate, and a thin high density dielectric film positioned between the first high density plate and the second high density plate, wherein the thin high density dielectric film has a high density dielectric film thickness less than the high voltage dielectric film thickness;
an etch stop layer overlying the high voltage capacitor and the high density capacitor, wherein the etch stop layer comprises an electrically insulating material; and
a second interlayer dielectric overlying the etch stop layer.

15. The integrated circuit of claim 14 further comprising:
a resistor overlying the substrate, wherein the resistor comprises a resistor plate.

16. The integrated circuit of claim 15 wherein the resistor plate, the second high voltage plate, and the first high density plate have about the same composition such that a mass percent of each element in the resistor plate, the second high voltage plate, and the first high density plate is within about 5 percent of each other.

17. The integrated circuit of claim 16 wherein the resistor plate comprises about 50 mass percent or more of a metal selected from the group consisting of titanium, tantalum, and a combination thereof.

18. The integrated circuit of claim 14 wherein:
the high voltage dielectric film thickness if from about 500 angstroms to about 2,000 angstroms; and
the high density dielectric film thickness is from about 100 angstroms to about 500 angstroms.

19. The integrated circuit of claim 14 further comprising:
a third high density plate directly underlying the first high density plate; and
a thick high density dielectric film positioned between the third high density plate and the first high density plate.

20. A method of producing an integrated circuit comprising:
forming a first high voltage plate in a first interlayer dielectric;
forming a thick dielectric layer overlying the first high voltage plate and the first interlayer dielectric;
forming a first electrode layer overlying the thick dielectric layer;
forming a thin dielectric layer overlying the first electrode layer, wherein a thickness of the thin dielectric layer is less than a thickness of the thick dielectric layer;
forming a second electrode layer overlying the thin dielectric layer;
forming a high density capacitor, wherein the high density capacitor comprises a portion of the first electrode layer, a portion of the second electrode layer, and a portion of the thin dielectric layer; and
forming a high voltage capacitor, wherein the high voltage capacitor comprises the first high voltage plate, a portion of the thick dielectric layer, and a portion of the first electrode layer.
